(19) United States
(12) Patent Application Publication
(10) Pub. No.: US 2025/0299906 A1
(43) Pub. Date: Sep. 25, 2025

(54) OPTICAL SYSTEM FOR A PLURALITY OF PRIMARY BEAMLETS, CHARGED PARTICLE MULTI-BEAM APPARATUS AND METHOD OF FOCUSING A PLURALITY OF PRIMARY BEAMLETS

(71) Applicant: ICT Intergrated Circuit Testing Gesellschaft für Halbleiterprüftechnik mbH, Heimstetten (DE)

(72) Inventors: Pieter Kruit, Delft (NL); Martin Kamerbeek, Delft (NL); Xiaoli Guo, Delft (NL); Henrik Gabold, Muenchen (DE)

(73) Assignee: ICT Intergrated Circuit Testing Gesellschaft für Halbleiterprüftechnik mbH, Heimstetten (DE)

(21) Appl. No.: 18/610,084

(22) Filed: Mar. 19, 2024

(51) Int. Cl. H01J 37/153; H01J 37/147

(52) U.S. Cl. CPC H01J 37/153; H01J 37/147; H01J 2237/0453; H01J 2237/049; H01J 2237/1205; H01J 2237/1534

(57) ABSTRACT

A multi-aperture lens plate of a multi-beam generator for a charged particle multi-beam apparatus is described. The multi-aperture lens plate includes an aperture lens plate body, the aperture lens plate body comprising: an array of N beamlet openings, the array of N beamlet openings having beamlet openings, the array of N beamlet openings configured to generate N primary charged particle beamlets, wherein N is a number >=2; and a plurality of correction openings through the aperture lens plate body configured to locally influence a lens field of the beamlet openings, wherein the correction openings are different than the beamlet openings.

### FIELD

Embodiments relate to charged particle beam devices, for example, for inspection system applications, testing system applications, defect review or critical dimensioning applications or the like. Embodiments also relate to methods of operation of a charged particle beam device, particularly to a method of generating a plurality of N primary charged particle beamlets to be focused on a specimen. More particularly, embodiments relate to charged particle beam devices being multi-beam high throughput electron beam inspection (EBI). Specifically, embodiments relate to a multi-aperture lens plate of a multi-beam generator, a multi-beam generator, a charged particle multi-beam apparatus configured to focus N primary charged particle beamlets on a specimen, and a method of generating a plurality of N primary charged particle beamlets to be focused on a specimen.

### BACKGROUND

Modern semiconductor technology is highly dependent on an accurate control of the various processes used during the production of integrated circuits. Accordingly, the wafers are inspected repeatedly in order to localize problems as early as possible. Furthermore, a mask or reticle is also inspected before the actual use during wafer processing in order to make sure that the mask accurately defines the respective pattern. The inspection of wafers or masks for defects may include the examination of the whole wafer or mask area, e.g. for 300 mm wafer production. Especially, the inspection of wafers during wafer fabrication beneficially includes the examination of the whole wafer area in such a short time that production throughput is not limited by the inspection process. The throughput is also beneficially increased in the event only portions of a wafer or a mask are inspected.

Scanning Electron Microscopes (SEM) have been used to inspect wafers. The surface of the wafer is scanned using e.g. a single finely focused electron beam. When the electron beam hits the wafer, secondary electrons and/or backscattered electrons, i.e. signal electrons, are generated and measured. A pattern defect at a location on the wafer is detected by, for example, comparing an intensity signal of the secondary electrons to, for example, a reference signal corresponding to the same location on the pattern. However, because of the increasing demands for higher resolutions, scanning the entire surface of the wafer takes a long time. Accordingly, using a conventional (single-beam) SEM for wafer inspection is difficult, since the approach does not provide the respective throughput.

Wafer and mask defect inspection in semiconductor technology needs high resolution and fast inspection tools, which cover high throughput, full wafer or mask application, or hot spot inspection. Electron beam inspection gains increasing importance because of the limited resolution of light optical tools, which are not able to handle the shrinking defect sizes. In particular, from the 20 nm node and beyond, the high-resolution potential of electron beam-based imaging tools is in demand to detect all defects of interest.

For example, document US 2017/287674 describes a particle-optical arrangement with a charged-particle source for generating a beam of charged particles, a multi-aperture plate arranged in a beam path of the beam of charged particles, wherein the multi-aperture plate has a plurality of apertures formed therein in a predetermined first array pattern. Document EP 3 703 100 describes a charged particle beam device with a specimen holder for holding a specimen, a source for producing a beam of charged particles, and an illuminator for converting said beam of charged particles into a plurality of charged particle beamlets and directing said plurality of charged particle beamlets onto said specimen.

In a multi-beam instrument, a plurality of electron beams may be used to inspect or image areas of the specimen, for example, a wafer. Generation of the beamlets for a multi-beam application can introduce a plurality of aberrations, which may be introduced by off-axis beamlets, a combination of individual beamlet forming elements and common beamlet forming elements, and/or other effects caused by the interaction of beamlets and the elements forming the beamlets.

In view of the above, a multi-aperture lens plate of a multi-beam generator, a multi-beam generator, a charged particle multi-beam apparatus, and a method of generating a plurality of N primary charged particle beamlets to be focused on a specimen are provided that are improved as compared to previous attempts.

### SUMMARY

In light of the above, a multi-aperture lens plate of a multi-beam generator, a multi-beam generator, a charged particle multi-beam apparatus, and a method of generating a plurality of N primary charged particle beamlets are provided. Further aspects, advantages, and features are apparent from the dependent claims, the description, and the accompanying drawings.

According to an embodiment, a multi-aperture lens plate of a multi-beam generator for a charged particle multi-beam apparatus is provided. The multi-aperture lens plate includes an aperture lens plate body having one or more layers, the aperture lens plate body comprising: an array of N beamlet openings through all of the one or more layers, the array of N beamlet openings having beamlet openings, the array of N beamlet openings configured to generate N primary charged particle beamlets, wherein N is a number >=2; and a plurality of correction openings through all of the one or more layers of the aperture lens plate body and configured to locally influence a lens field of the beamlet openings, wherein the correction openings are different than the beamlet openings.

According to an embodiment, a multi-beam generator for a charged particle multi-beam apparatus is provided. The multi-beam generator includes a charged particle emitter configured to emit a primary charged particle beam; a multi-aperture lens plate being arranged for being illuminated with the primary charged particle beam, the multi-aperture lens plate comprising: an aperture lens plate body, the aperture lens plate body including: an array of N beamlet openings, the array of N beamlet openings having beamlet openings, the array of N beamlet openings configured to generate N primary charged particle beamlets, wherein N is a number >=2; and a plurality of correction openings through the aperture lens plate body configured to locally influence a lens field of the beamlet openings, wherein the correction openings are different than the beamlet openings; and an aperture plate in a field-free region, distant and downstream of the multi-aperture lens plate with an aperture plate body having a plurality of N openings for passing of the N primary charged particle beamlets, the aperture plate body configured to block electrons passing through the correction openings. Particularly, according to some embodiments, which can be combined with other embodiments described herein, the multi-aperture lens plate is arranged for being directly illuminated with the primary charged particle beam, i.e. without having a condenser lens or another lens in between the charged particle emitter and the multi-aperture lens plate.

According to an embodiment, a multi-beam generator for a charged particle multi-beam apparatus is provided. The multi-beam generator includes a charged particle emitter configured to emit a primary charged particle beam; a multi-aperture lens plate of any of the embodiments described herein, the multi-aperture lens plate is arranged for being illuminated with the primary charged particle beam; and one or more electrodes with a common opening configured for passing of at least one of the primary charged particle beam or the N primary charged particle beamlets, the one or more electrodes being configured to generate an electric field on the multi-aperture lens plate to focus the N primary charged particle beamlets in a plane downstream of the multi-aperture lens plate.

According to an embodiment, a charged particle multi-beam apparatus configured to focus N primary charged particle beamlets on a specimen is provided. The charged particle multi-beam apparatus includes a multi-beam generator of any of the embodiments described herein.

According to an embodiment, a method of generating a plurality of N primary charged particle beamlets to be focused on a specimen is provided. The method includes generating a primary charged particle beam with a charged particle emitter; illuminating a multi-aperture lens plate with the primary charged particle beam; generating beamlets, comprising: generating N primary charged particle beamlets generated with an array of N beamlet openings; and generating first dummy beamlets generated with a plurality of correction openings; focusing the N primary charged particle beamlets with an electric field generated at the multi-aperture lens plate with one or more electrodes, the N primary charged particle beamlets are focused in a plane downstream of the multi-aperture lens plate; and blocking at least the first dummy beamlets, particularly in a field-free region, downstream of the multi-aperture lens plate.

Embodiments are also directed at apparatuses for carrying out the disclosed methods and include apparatus parts for performing each described method features. The method features may be performed by way of hardware components, a computer programmed by appropriate software, by any combination of the two or in any other manner. Furthermore, embodiments are also directed at methods which the described apparatus operates with. Embodiments include method features for carrying out every function of the apparatus.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 shows a schematic view of a portion of charged particle multi-beam apparatus having a multi-beam generator with the multi-aperture lens plate according to embodiments described herein;

FIG. 2 shows a schematic view of a multi-aperture lens plate according to embodiments of the present disclosure and having beamlet openings and correction openings;

FIG. 3 shows a schematic view of a multi-aperture lens plate according to embodiments of the present disclosure and having beamlet openings compensating a distortion;

FIG. 4 shows a schematic view of a multi-aperture lens plate according to embodiments of the present disclosure and having beamlet openings and further openings;

FIG. 5 shows a schematic view of a multi-aperture lens plate according to embodiments of the present disclosure;

FIG. 6 shows a schematic view of an aperture plate having openings for a plurality of primary beamlets to be focused on a specimen, which can, for example, be included in a collimator, collimating the primary beamlets;

FIGS. 7A and 7B show schematic views of a portion of a charged particle multi-beam apparatus having a multi-beam generator with the multi-aperture lens plate according to embodiments described herein;

FIGS. 8A and 8B show schematic views of a portion of a charged particle multi-beam apparatus having a multi-beam generator with the multi-aperture lens plate according to embodiments described herein;

FIG. 9 shows a schematic view of a charged particle multi-beam apparatus according to embodiments described herein; and

FIG. 10 shows a flow chart illustrating methods of generating a plurality of N primary charged particle beamlets to be focused on a specimen according to embodiments of the present disclosure.

### DETAILED DESCRIPTION OF EMBODIMENTS

Reference will now be made in detail to the various embodiments, one or more examples of which are illustrated in the figures. Within the following description of the drawings, the same reference numbers refer to the same components. The differences with respect to individual embodiments are described. Each example is provided by way of explanation and is not meant as a limitation. Further, features illustrated or described as part of one embodiment can be used on or in conjunction with other embodiments to yield yet a further embodiment. The description is intended to include the modifications and variations.

Without limiting the scope of protection of the present application, in the following, the charged particle multi-beam apparatus or components thereof will exemplarily be referred to as a charged particle multi-beam apparatus, including a primary electron beam or primary electron beamlets and the detection of secondary or backscattered particles, such as electrons. As described herein, discussions and descriptions relating to the detection are exemplarily described with respect to electrons in scanning electron microscopes. Other types of charged particles, e.g. positive ions, could be emitted and/or detected by the device in a variety of different instruments. Embodiments relate to a primary beam, primary beamlets, and one or more signal beams of e.g. electrons. The primary beam, the primary beamlets, and/or the one or more signal beams may be provided by other charged particles as electrons. Signal beamlets may additionally or alternatively include photons.

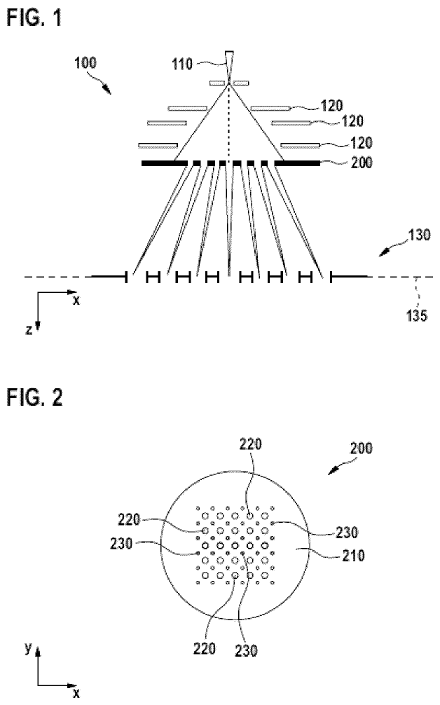

FIG. 1 shows a portion of a charged particle multi-beam apparatus. The charged particle multi-beam apparatus includes a multi-beam generator 100. The multi-beam generator includes a charged particle beam source, two or more electrodes 120, and the multi-aperture lens plate 200. The charged particle beam source includes an emitter 110, which emits a primary charged particle beam, for example an electron beam. According to embodiments described herein, the multi-beam generator is configured to generate an array of primary charged particle beamlets. The charged particle beam source emits a primary beam. The multi-aperture lens plate 200 generates primary particle beamlets from the primary beam. The one or more electrodes 120 and the multi-aperture lens plate may operate as electrodes of micro-lenses for the primary charged particle beamlets. Accordingly, the one or more electrodes 120 can be lens electrodes. Particularly, the one or more electrodes can include an opening for the primary beam. The multi-aperture lens plate includes openings for generating the primary charged particle beamlets. The one or more electrodes, i.e. electrodes common to the primary charged particle beam or the primary charged particle beamlets and the multi-aperture lens plate act together, particularly as if the beamlets would be influenced by individual lenses corresponding to the openings or apertures in the multi-aperture lens plate.

The one or more electrodes and the multi-aperture lens plate focus the primary charged particle beamlets in a plane 135 downstream of the multi-aperture lens plate. The primary charged particle beamlets generated by the multi-aperture lens plate or aperture lens array are collimated with a collimator 130. For example, the collimator can include one or more of: a deflector array shown in FIG. 1 and a lens. A diverging pattern or array of primary charged particle beamlets is redirected by the collimator 130. The collimated beamlets may travel essentially parallel and/or along optical axes of an objective lens unit onto a sample or a specimen. According to some embodiments, which can be combined with other embodiments described herein, the collimator 130 can be located in or near the plane 135, in which the primary charged particle beamlets are focused.

The multi-aperture lens plate 200 shown in FIG. 1, can be a multi-aperture lens plate according to embodiments of the present disclosure. Embodiments of the present disclosure allow for a regular pattern of primary charged particle beamlets, for example, a rectangular or square pattern. Particularly, the regular pattern of primary charged particle beamlets can be provided in the plane 135, i.e. in a plane of focused primary charged particle beamlets. Further aberrations of the aperture lens array (ALA) or multi-aperture lens plate can be reduced. For example, the aberrations of the micro lenses in the multi-aperture lens plate can be smaller than the geometrical image of the charged particle emitter.

Embodiments of the present disclosure allow to reduce the optical effect generated by neighboring holes in the multi-aperture lens plate (or the ALA), to compensate for distortions created by the micro-electrodes, i.e. the one or more electrodes 120 of the multi-beam generator 100, and/or to reduce the effect of penetration of the electric field through the openings in the multi-aperture lens plate (or the ALA).

FIG. 2 shows a multi-aperture lens plate 200. The multi-aperture lens plate includes an aperture lens plate body 210. A plurality of various openings are provided in the aperture lens plate body. Particularly, the openings are provided through the aperture lens plate body, for example, to allow for passing of electrons (or charged particles, in general) the various openings and through the multi-aperture lens plate. As shown in FIG. 2 the various openings include an array of beamlet openings 220. Further, a plurality of correction openings are provided.

According to an embodiment; a multi-aperture lens plate of a multi-beam generator for a charged particle multi-beam apparatus is provided. The multi-aperture lens plate (or ALA) includes an aperture lens plate body having one or more layers. The aperture lens plate body includes an array of N beamlet openings through all of the one or more layers, the array of N beamlet openings being configured to generate N primary charged particle beamlets, wherein N is a number >=2, and a plurality of correction openings through all of the one or more layers the aperture lens plate body. The correction openings are configured to locally influence the lens field of the beamlet openings, wherein the correction openings are different than the beamlet openings. For example, the array of N beamlet openings can be rectangular or square. The openings being provided through all of the one or more layers is understood such that for a case of the aperture lens body comprising or consisting of a stack of layers, the openings are formed through the entire stack. The electrons through the beamlet openings pass through the aperture lens plate body, e.g. up to the specimen and the electrons through the correction openings pass through the aperture lens plate body, e.g. up to a blocking element distant from the aperture lens plate body, e.g. in a field free region of the multi-aperture lens. Further, it may be understood that aperture lens plate body having one or more layers, may be an aperture lens plate body consisting of one or more layers, particularly one or more layers being in direct contact with each other. The aperture lens plate body consisting of one or more layers con be included in a multi-aperture lens plate, comprising the aperture lens plate body, a support for the aperture lens plate, or further elements of the multi-aperture lens plate.

FIG. 2 exemplarily shows an array of 25 (5×5) beamlet openings. According to embodiments of the present disclosure, there can be 50 or more primary beamlets, such as 200 or more primary beamlets, or even a thousand or more primary beamlets. The array shown in FIG. 2 is a square array. Also rectangular arrays may be provided.

An opening of rectangular or square beamlet openings cause an octupole effect by the neighboring beamlet openings of a beamlet opening. The neighboring beamlet openings “pull” the equipotential surfaces into the holes of the beamlet opening. The correction openings 230 are provided such that the correction openings “pull” the equipotential planes such that the multipole effect is not fourfold but eightfold, which reduces the aberration effect.

According to some embodiments, which can be combined with other embodiments described herein, the beamlet openings can be circular. Further, the correction openings can be circular. Accordingly, the octupole effect generated by the array is no compensated by non-circular openings. Further, the octupole effect generated by the array is not generated by recesses or indentations. According to embodiments of the present disclosure, the plurality of correction openings extend through the aperture lens body, particularly while allowing electrons of a primary charged particle beam to pass through the aperture lens plate body.

As shown in FIG. 2, the correction openings are closer to the beamlet openings than the neighboring beamlet openings. The correction openings may have a different diameter than the beamlet openings. The correction openings can be smaller than the beamlet openings to have a symmetric 16-pole effect. Further, the smaller correction openings allow to provide through holes within the array of beamlet openings. According to some embodiments, which can be combined with other embodiments described herein, the beamlets in addition to the N primary charged particle beamlets to be focused on a specimen, can be blocked downstream of the multi-aperture lens plate. Advantageously, the plurality of correction openings can be manufactured on the same fabrication operation as the array of beamlet openings.

According to some embodiments, which can be combined with other embodiments described herein, the correction openings can have a diameter of 60% of the diameter of the beamlet openings or smaller. Particularly the diameter of the correction openings can be from 45% to 55% of the diameter of the beamlet openings. For example, the beamlet openings can have a diameter of 30 to 70 μm and the correction openings have a diameter of 10 to 30 μm.

As shown in FIG. 2, while next neighboring beamlet openings 220 of a first beamlet opening are disposed in x-direction and y-direction, next neighboring correction openings of the first beamlet opening are provided in a diagonal direction (x-y-direction), i.e. a direction having an angle of 45° as compared to a x-direction or y-direction. According to some embodiments, a first neighboring beamlet opening of a first beamlet opening of the array of N beamlet openings is in a first direction having a first vector selected from the group consisting of: [1,0], [0,1], [−1,0], and [0,−1] and a first neighboring correction opening of the first beamlet openings is in a second direction selected from the group consisting of: [1,1], [1,−1], [−1,1] and [−1,−1]. For example, neighboring beamlet openings of a first beamlet opening of the array of N beamlet openings are in directions having vectors being [1,0], [0,1], [−1,0], and [0,−1] and neighboring correction openings of the first beamlet openings are in directions having vectors being [½,½], [½,−½], [−½,½] and [−½,−½].

Yet further, additionally or alternatively, the additional correction openings, i.e. the correction openings being through-openings are located at equal distance or essentially equal distance to surrounding beamlet openings of the array of N beamlet openings. The term “essentially equal distance” is understood as an “equal distance” considering a deviation for manufacturing inaccuracies and/or a deviation for a distortion compensation according to some embodiments of the present disclosure.

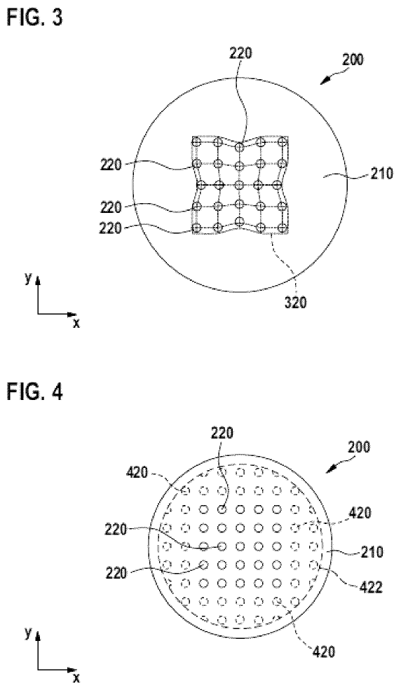

FIG. 3 shows a multi-aperture lens plate 200 according to some embodiments of the present disclosure to compensate for a distortion.

As described herein, the one or more electrodes 120 (see FIG. 1) and the multi-aperture lens plate 200 generate micro-lenses for the primary charged particle beamlets. Additionally, the one or more electrodes can generate macro-lens in the multi-beam generator 100. Higher order effects, such as third order effects, of the micro-lens may introduce distortion to the array of primary charged particle beamlets. Accordingly, the pattern of the primary charged particle beamlets in the plane of the collimator 130 (see FIG. 1) may be distorted. Even though a correction might be provided by individual alignment deflectors of the collimator 130, the misalignment of the array of the primary charged particle beamlets results in other downturns of the optical system. For example, one or more aperture plates having a plurality of openings may be provided between the ALA or multi-aperture lens plate and the collimator, wherein the primary charged particle beamlets beneficially pass through the plurality of openings of the one or more aperture plates. Further, the displacement in the plane of the collimator 130 may exceed the diameter of the openings in the collimator, which makes compensation in the collimator difficult or impossible. According to some embodiments, the beam openings in a collimator can have a size of 20% to 60% of the local pitch in the plane of the collimator.

According to some embodiments, which can optionally be combined with other embodiments described herein, the position of the beamlet openings in the multi-aperture lens plate is moved as compared to a pattern of the beamlet openings with constant pitch.

The multi-aperture lens plate 200 shown in FIG. 2 includes the aperture lens plate body 210. The plurality of beamlet openings 220 are shown. The dashed lines 320 show a square corresponding to the array of beamlet openings, wherein a distortion is added to the pattern of beamlet openings to compensate for the distortion described above. For example, the outer beamlet openings are displaced inwardly.

According to some embodiments, which can be combined with other embodiments described herein, a position of beamlet openings can change with a distance of the beamlet openings to a central point according to both a linear and a third order function of the distance, particularly a position of beamlet openings can change additionally with a distance of the beamlet openings to a central point according a fifth order function of the distance.

According to some embodiments, which can be combined with other embodiments described herein, the distance of the beamlet openings is changed by a function providing a pin-cushion shape, i.e. a distortion added to the pattern of openings has a pin-cushion shape. Distances between adjacent apertures are, for example, continuously increasing with increasing distance from the center.

According to some embodiments, which can be combined with other embodiments described herein, the function for distortion correction can be any polynomic function with an order of up t 5 or even up to 7.

According to an embodiment, a multi-aperture lens plate of a multi-beam generator for a charged particle multi-beam apparatus is provided. The multi-aperture lens plate includes an aperture lens plate body. The aperture lens plate body includes an array of N beamlet openings configured to generate N primary charged particle beamlets, wherein N is a number >=2. A position of beamlet openings of the array of N beamlet openings changes with a distance of the beamlet openings to a central point according to both a linear and a third order function of the distance. Further aspects, advantages, and features described in other independent and dependent claims, the description, and the accompanying drawings may be combined with the multi-aperture lens plate having a distorted pattern.

FIG. 4 shows a multi-aperture lens plate 200 according to some embodiments of the present disclosure to compensate for a field penetration.

The electric field generated on the multi-aperture lens plate, e.g. by the one or more electrodes 120 (see FIG. 1) generates a lens effect. The equipotential planes of the electric field “bulge out’ from the beamlet openings in the multi-aperture lens plate. For example, electric field may bulge out of the beamlet openings at a side of the multi-aperture lens plate opposite to an electrode of the one or more electrodes. In an example with electrodes 120 on both sides, a net field resulting from all lens generating components exists on one side, and the net field will bulge out as described herein. Accordingly, the plurality of electric fields or equipotential planes are provided, i.e. for each of the beamlet openings. The plurality of electric fields or equipotential planes may connect at some distance from the multi-aperture lens plate. A weak field is formed, which is referred to as field penetration. The field lines of the weak field extend to the next electrode or an auto portion of the multi-aperture lens plate. For a rectangular or square array of beamlet openings, the field will not be circular symmetric and may, thus, cause aberrations. For example, an undesired deflection of outer primary charged particle beamlets may occur. Accordingly, embodiments of the present disclosure may provide for a circular pattern of openings. For example, the diameter of the pattern of openings may be larger than the dimension, e.g. a diagonal, of the array of beamlet openings.

FIG. 4 shows the multi-aperture lens plate 200 having the aperture lens plate body 210. An array of 25 (5×5) beamlet openings 220 is shown in FIG. 4. The array of beamlet openings for a first pattern, a square array having an equal pitch in x-direction and y-direction is shown in FIG. 4. The first pattern is provided in the first area. Further openings 420 are provided in the aperture lens plate body, and particularly through the aperture lens plate body to extend the first pattern beyond the first area. The second pattern with a second area larger than the first area is provided. For example, the second area can be circular as indicated by dashed line 422.

According to some embodiments, which can be combined with other embodiments described herein, if the first array is a square pattern of, for example, 15×15 beamlet openings, the second pattern may have an additional 10 to 20 further openings along a diameter of the circle. If the first array is a square pattern of, for example, 25×25 beamlet openings, the second pattern may have an additional 16 to 30 further openings along a diameter of the circle. According to some embodiments, which can be combined with other embodiments described herein, the total number of openings in the multi-aperture lens plate, i.e. beamlet openings and further openings, along diameter of the circular second area can be from 150% to 250% of the number of beamlet openings along a side of a wrecked angular or square array of beamlet openings.

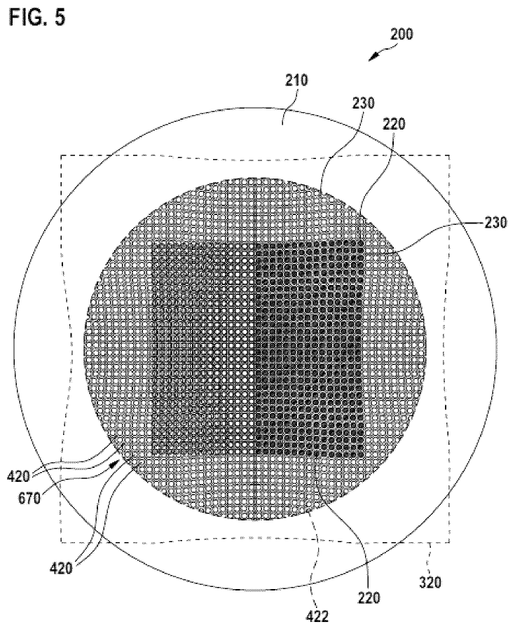

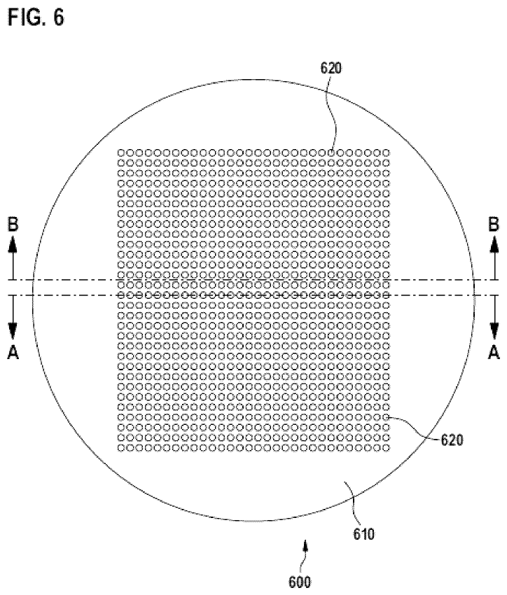

FIG. 5 shows a multi-aperture lens plate 200. FIG. 6 shows an aperture plate 600. The aperture plate 600 can be used in combination with the multi-aperture lens plate 200. For example, the aperture plate 600 can be provided between a collimator and the multi-beam generator, i.e. between the collimator and the multi-aperture lens plate. The aperture plate may be included in the collimator.

The multi-aperture lens plate 200 includes the aperture lens plate body 210. As shown in FIG. 5, the aperture lens plate body may be circular. According to some embodiments, which can be combined with other embodiments described herein, the aperture to lens plate body may have a polygon shape, e.g. a hexagon or an octagon, or may have some non-circular shape to allow for a predetermined orientation during assembly, i.e. to have the pattern of the array of beamlet openings properly oriented with respect to a rotation.

According to some embodiments, which can be combined with other embodiments described herein, the aperture lens plate body can include a foil having a thickness of 20 μm or below, particularly 5 μm or below, and wherein the array of N beamlet openings and the plurality of correction openings are provided through the foil. According to some embodiments, the aperture lens plate body may consist of the foil.

The multi-aperture lens plate 200 shown in FIG. 5 provides a combination of a first aspect of correction openings 230 according to embodiments of the present disclosure, a second aspect of a distortion of the pattern of beamlet openings as illustrated by the dashed line 320 and according to embodiments of the present disclosure, and a third aspect of further openings 420 to extend the pattern generated by the beamlet openings and correction openings according to embodiments of the present disclosure. According to some embodiments, which can be combined with other embodiments described herein, the multi-aperture lens plate according to embodiments of the present disclosure includes at least one of the first aspect, the second aspect and the third aspect.

In FIG. 5, the array of N beamlet openings is the square array with N=900, i.e. 30×30 beamlet openings. On the right-hand side of the array, which is indicated by the black beamlet openings 220, the beamlet openings are positioned to compensate for distortion as indicated by the dashed line 320. On the left-hand side of the array, the beamlet openings are shown without the distortion. The left-hand side illustration is for illustrating purposes only to better show the corrected position of the beamlet openings and the correction openings. As can be seen by the pattern 670, showing the openings in the aperture lens plate body, also the beamlet openings and correction openings on the left-hand side include a positioning or position correction to compensate for the distortion.

According to some embodiments, which can be combined with other embodiments described herein, the pattern formed in the area of the beamlet openings can be extended into a larger area, particularly wherein a larger area is circular. As shown in FIG. 5, the pattern of 30×30 beamlet openings includes the beamlet openings and the correction openings as described herein. Further, the pattern of beamlet openings and correction openings includes a distortion correction, i.e. the pitch changes with the distance from the center. The distortion correction applies to the beamlet openings and similarly to the correction openings. Accordingly, when extending the first pattern to the larger second pattern, the further openings include openings corresponding to the correction openings. Additionally or alternatively, that distortion correction is extended for the second pattern over the second area.

According to some embodiments, which can be combined with other embodiments described herein, the extended second pattern can have two or more regions. The first region is the region of the first pattern. The second region can be outside the first pattern in continuous the distortion correction of the first pattern. A third region may be outside the second region, wherein a distortion correction is reduced as compared to the second region. In some example, the distortion correction may be reduced to zero. For example, the further openings may have a constant distance in the third region. According to some implementations, the above-described second region may be omitted, such that the above-described third region is outside the first region of the first pattern, and the wherein a distortion correction is reduced as compared to the first region. In some example, the distortion correction may be reduced to zero. For example, the further openings may have a constant distance in the third region.

As shown in FIG. 4, the first pattern within a first area can be extended to a second pattern in a second area, wherein the first pattern has a constant pitch. Accordingly, also the second pattern has a constant pitch. As shown in FIG. 3, the first pattern can include distortion correction within a first area. Accordingly, also the extended second pattern in the second area continues that distortion correction. As shown in FIG. 2, the first pattern includes beamlet openings. Accordingly, the extended second pattern in the second area also continues to include beamlet openings. It is to be understood, that as shown in FIG. 5, if a combination of aspects is provided, the aspects provided in the first pattern also extend into the larger second pattern.

FIG. 6 shows an aperture plate 600, wherein the array of openings 620 corresponds to the multi-aperture lens plate 200 of FIG. 5. The plurality of openings 620 is provided in an aperture plate body 610. The plurality of openings are configured for passing of the primary charged particle beamlet. Accordingly, the array of openings shown in FIG. 6 include N openings with N=900, i.e. an array of 30×30 openings. The N primary charged particle beamlets to be focused on a specimen can pass through the aperture plate 600. Other electrons, for example electrons passing through the correction openings and/or the further openings, are blocked by the aperture plate 600. Charged particle beamlets other than the N primary charged particle beamlets are blocked.

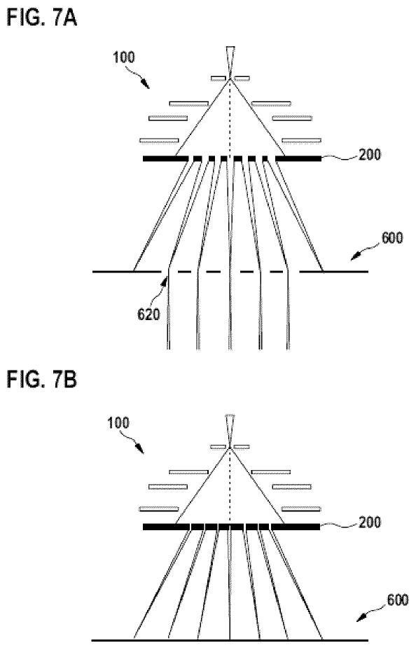

This is also illustrated in FIGS. 7A and 7 B, wherein FIGS. 7A and 7 B each show a multi-beam generator 100, including the multi-aperture lens plate 200 and further the aperture plate 600. FIG. 7A is a sectional view according to section A-A in FIG. 6 and FIG. 7B is a sectional view according to section B-B in FIG. 6. The number of openings is reduced for easier illustration. Along section A-A-beamlets outside the array of openings 620 are blocked. In other words, beamlets corresponding to further openings 420 in the multi-aperture lens plate are blocked. Along section B-B beamlets corresponding to the correction openings 230 are blocked. According to some embodiments, which can be combined with other embodiments described herein, a charged particle multi-beam apparatus includes an aperture plate with an aperture plate body having a plurality of N openings for passing of the N primary charged particle beamlets, the aperture plate body blocking electrons passing through the openings, e.g. the correction openings or the further openings. According to some embodiments, which can be combined with other embodiments described herein, the aperture plate can be in a field free region with respect to the field of the one or more electrodes 120 and the multi-aperture lens plate.

According to yet further embodiments, which can be combined with other embodiments described herein, the array of openings 620 in the aperture plate 600 has a constant pitch. The pattern of openings is non-distorted, since the distortion compensation in the multi-aperture lens plate generates a non-distorted array of primary charged particle beamlets in the plane of the aperture plate. According to some embodiments, which can be combined with other embodiments described herein, the aperture plate can be included in the collimator or can be a part of the collimator.

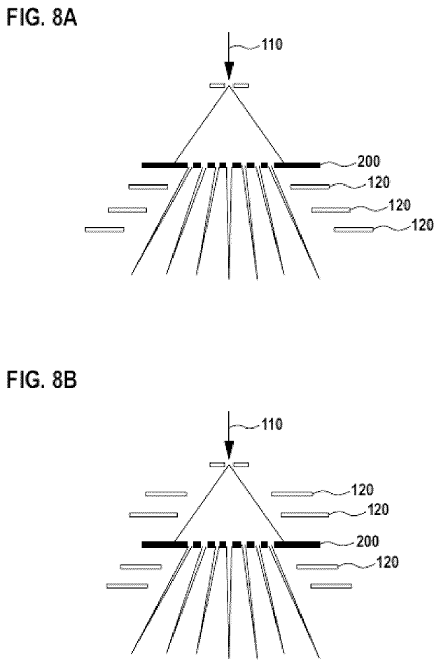

According to some embodiments, and as shown in FIG. 1, the multi-aperture lens plate 200 can be provided downstream of the one or more electrodes 120. In other words, the one or more electrodes 120 are provided between the multi-aperture lens plate 200 and the charged particle beam source and/or the emitter 110, respectively According to yet further embodiments, which can be combined with other embodiments described herein, the one or more electrodes 120 can be downstream of the multi-aperture lens plate 200. In other words, the multi-aperture lens plate 200 can be between the one or more electrodes 120 and the charged particle beam source and/or the emitter 110, respectively. This is, for example, shown in FIG. 8A. According to yet further embodiments, as exemplarily shown in FIG. 8B, two or more electrodes 120 can be provided. The multi-aperture lens plate 200 can be provided between two electrodes of the two or more electrodes 120. According to embodiments of the present disclosure, the one or more electrodes 120 may have aperture openings through which the primary charged particle beam can pass. For example, each of the one or more electrodes may have one opening through which the primary charged particle beam can pass, or with respect to electrodes downstream of the multi-aperture lens plate, each of the one or more electrodes may have one opening through which the primary charged particle beamlets can pass.

According to embodiments of the present disclosure, a multi-beam generator for a charged particle multi-beam apparatus is provided. The multi-beam generator includes a charged particle emitter configured to emit a primary charged particle beam and a multi-aperture lens plate according to any of the embodiments described herein, wherein the multi-aperture lens plate is arranged for being illuminated with the primary charged particle beam. The multi-beam generator further includes one or more electrodes with a common opening configured for passing of at least one of the primary charged particle beam or the N primary charged particle beamlets, the one or more electrodes being configured to generate an electric field on the multi-aperture lens plate to focus the N primary charged particle beamlets in a plane downstream of the multi-aperture lens plate.

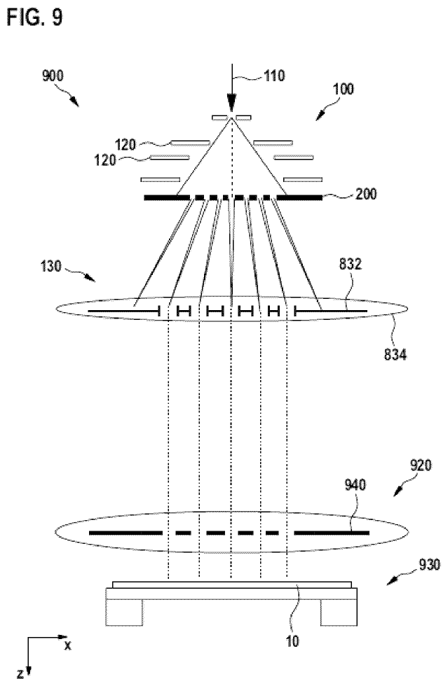

FIG. 9 shows a charged particle multi-beam apparatus 900. The charged particle multi-beam apparatus includes a multi-beam generator 100. The multi-beam generator may include a charged particle beam source, one or more electrodes 120, and a multi-aperture lens plate 200 (or aperture lens array ALA). The charged particle beam source includes an emitter 110, which emits a primary charged particle beam, for example an electron beam.

Particularly, a single emitter can be provided, for example a high brightness emitter. A charged particle beam emitter as described herein may be a cold field emitter (CFE), a Schottky emitter, a thermal field emitter (TFE) or another high current, high brightness charged particle beam source (such as an electron beam source). A high current is considered to be 0.5 mA/sr or above such as 0.5 mA/sr to 1 mA/sr.

According to embodiments described herein, the multi-beam generator is configured to generate an array of primary charged particle beamlets. The aperture lens array or multi-aperture lens plate 200 generates primary charged particle beamlets from the primary charged particle beam. The one or more electrodes and the multi-aperture lens plate may operate as electrodes of an electrostatic lens.

The primary charged particle beamlets generated by the multi-aperture lens plate are collimated with a collimator 130. For example, the collimator can include at least one of a deflector array 832 and a lens 834. FIG. 9 shows both, the deflector array and the lens. The collimated beamlets may travel essentially parallel and/or along optical axes of an objective lens 920 onto a sample or a specimen 10.

According to some embodiments, which can be combined with other embodiments described herein, the collimator can be provided in or near the focus plane of the primary charged particle beamlets. For example, a distance between the multi-aperture lens plate 200 and the collimator 130 can be at least 10 times larger than a distance between the emitter 110 and the multi-aperture lens plate 200. Accordingly, a pitch of beamlet openings in the multi-aperture lens plate of about 30 μm to 80 μm may result in a pitch of openings in the collimator of 0.5. mm or more. According to some embodiments, which can be combined with other embodiments described herein, the pitch of the openings in the collimator can respond to the pitch of the primary charged particle beamlets on the specimen 10. For example, the pitch on the specimen can be from 0.7 mm to 2 mm.

According to some embodiments, which can be combined with other embodiments described herein, the plane of focus of the primary charged particle beamlets is a flat plane, particularly as the primary charged particles travel substantially parallel from the collimator towards the objective lens and on the specimen.

The objective lens 920 is schematically illustrated in FIG. 9. The objective lens 920 provides lenslets for each of the primary charged particle beamlets. For example, the objective lens 920 can include a plurality of electrodes having an array of holes or openings. The plurality of electrodes may act as electrostatic lenses on primary charged particle beamlets passing through corresponding holes and openings of the plurality of electrodes. The objective lens unit can be provided as a deceleration lens. The plurality of electrodes may be set to potentials decelerating the primary beamlets before impinging on the specimen. The objective lens 920 focuses the primary charged particle beamlets, particularly individually, on the specimen 10. The specimen 10 can be provided on a stage 930, for example, a wafer holder with drives. For example, drives may move a specimen or sample in x, y, and z direction.

According to some embodiments, which can be combined with other embodiments described herein, signal beamlets are generated upon impingement of the primary charged particle beamlets on the specimen 10. The signal beamlets can be detected with a detection unit 940. According to some embodiments, which can be combined with other embodiments described herein, the detection unit can be provided within the objective lens 920 or between the objective lens 920 and the collimator 130. According to embodiments described herein, one detection surface can be provided per signal beamlet. The detection unit can be a detector array.

According to embodiments herein, which can be combined with other embodiments, a signal (charged particle) beamlet is referred to as a beam of secondary and/or backscattered electrons. The signal beamlet is generated by the impingement of the primary charged particle beamlets on a specimen or by backscattering of the primary charged particle beamlets from the specimen. A primary charged particle beam or a primary charged particle beamlet is generated by a particle beam source or a multi-beam generator, respectively, and is guided and deflected on a specimen to be inspected or imaged. According to some embodiments, which can be combined with other embodiments described herein, a scanning deflector can be provided to scan the plurality of primary charged particle beamlets over the specimen for image generation of the specimen. A charged particle multi-beam apparatus according to embodiments of the present disclosure can be a scanning charged particle multi-beam apparatus.

A “specimen” or “sample” as referred to herein, includes, but is not limited to, wafers, semiconductor wafers, semiconductor workpieces, photolithographic masks and other workpieces such as memory disks and the like. Embodiments may be applied to any workpiece on which material is deposited or any workpiece which is structured. According to some embodiments, which can be combined with other embodiments described herein, the apparatus and the method are configured for or are applied for electron beam inspection, for critical dimensioning applications and defect review applications.

According to an embodiment, a charged particle multi-beam apparatus configured to focus N primary charged particle beamlets on a specimen is provided. The charged particle multi-beam apparatus includes a multi-beam generator according to any of the embodiments described herein, and particularly the multi-beam generator including the multi-aperture lens plate according to embodiments described herein.

The charged particle multi-beam apparatus may further include an aperture plate with an aperture plate body having a plurality of N openings for passing of the N primary charged particle beamlets, the aperture plate body blocking electrons passing through other openings in the ALA, e.g. the correction openings. For example, the aperture plate can be provided by the collimator 130 or can be included in the collimator 130. Further, an additional aperture plate for blocking of undesired electrons can be provided between the collimator 130 and the multi-aperture lens plate 200.

According to some embodiments, which can be combined with other embodiments described herein, and as particularly described with respect to FIGS. 4, 5, 6, 7A and 7B, a charged particle multi-beam apparatus configured to focus N primary charged particle beamlets on a specimen can be provided, wherein the array of N beamlet openings and the plurality of correction openings form a first pattern within a first area, wherein further openings are provided in the aperture lens plate body to extend the first pattern beyond the first area to form a second pattern with a second area larger than the first area. For example, the second pattern has an essentially circular shape.

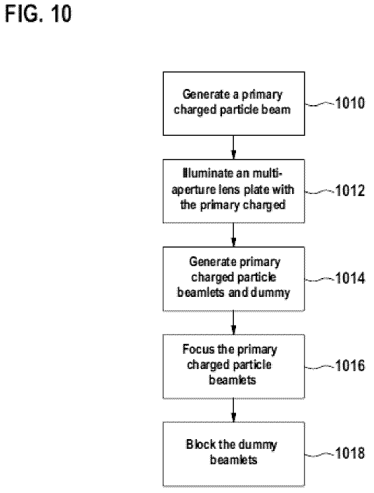

FIG. 10 shows a flowchart illustrating methods of generating a plurality of N primary charged particle beamlets to be focused on a specimen. At box 1010, a primary charged particle beam is generated with a charged particle emitter. A multi-aperture lens plate is illuminated with the primary charged particle beam at box 1012. Thereby, beamlets are generated. At box 1014 N primary charged particle beamlets are generated with an array of N beamlet openings and first dummy beamlets are generated with a plurality of correction openings. For example, a multi-beam generator focuses the N primary charged particle beamlets with an electric field generated at the multi-aperture lens plate with one or more electrodes as depicted by box 1016. The N primary charged particle beamlets can be focused in a plane downstream of the multi-aperture lens plate. At box 1018, at least the first dummy beamlets are blocked. Particularly, the first dummy beamlets can be blocked in a field-free region, downstream of the multi-aperture lens plate.

According to some embodiments, which can be combined with other embodiments described herein, a method may include generating second dummy beamlets with further openings extending beyond a first area of the array of N beamlet openings and the plurality of correction openings. The second dummy beamlets can be blocked.

The present disclosure discloses a plurality of embodiments, some of which are as described below: Embodiment 1. A multi-aperture lens plate of a multi-beam generator for a charged particle multi-beam apparatus, comprising: an aperture lens plate body having one or more layers, the aperture lens plate body comprising: an array of N beamlet openings through all of the one or more layers, the array of N beamlet openings having beamlet openings, the array of N beamlet openings configured to generate N primary charged particle beamlets, wherein N is a number >=2; and a plurality of correction openings through all of the one or more layers of the aperture lens plate body and configured to locally influence a lens field of the beamlet openings, wherein the correction openings are different than the beamlet openings.

Embodiment 2. The multi-aperture lens plate of embodiment 1, wherein the beamlet openings are circular.

Embodiment 3. The multi-aperture lens plate of any of embodiments 1 to 2, wherein the correction openings are circular.

Embodiment 4. The multi-aperture lens plate of embodiment 1, wherein the beamlet openings are circular, wherein the correction openings are circular and have a different diameter than the beamlet openings.

Embodiment 5. The multi-aperture lens plate of any of embodiments 1 to 4, wherein the correction openings have a diameter of 60% of the diameter of the beamlet openings or smaller, particularly from 45% to 55% of the diameter of the beamlet openings.

Embodiment 6. The multi-aperture lens plate of any of embodiments 1 to 5, wherein the beamlet openings have a diameter of 30 to 70 μm and the correction openings have a diameter of 10 to 30 μm.

Embodiment 7. The multi-aperture lens plate of any of embodiments 1 to 6, wherein the array of N beamlet openings is rectangular or square.

Embodiment 8. The multi-aperture lens plate of any of embodiments 1 to 7, wherein a first neighboring beamlet opening of a first beamlet opening of the array of N beamlet openings is in a first direction having a first vector selected from the group consisting of: [1,0], [0,1], [−1,0], and [0,−1] and a first neighboring correction opening of the first beamlet opening is in a second direction selected from the group consisting of: [½,½], [½, −½], [−½,½] and [−½,−½].

Embodiment 9. The multi-aperture lens plate of any of embodiments 1 to 8, wherein the plurality of correction openings is located at equal distance to surrounding beamlet openings of the array of N beamlet openings.

Embodiment 10. The multi-aperture lens plate of any of embodiments 1 to 9, wherein a position of beamlet openings changes with a distance of the beamlet openings to a central point according to a linear function, a third order function, and a fifth order function of the distance.

Embodiment 11. The multi-aperture lens plate of any of embodiments 1 to 10, wherein the aperture lens plate body includes a foil having a thickness of 20 μm or below, and wherein the array of N beamlet openings and the plurality of correction openings are provided through the foil.

Embodiment 12. A multi-beam generator for a charged particle multi-beam apparatus, comprising a charged particle emitter configured to emit a primary charged particle beam; a multi-aperture lens plate being arranged for being illuminated with the primary charged particle beam, the multi-aperture lens plate comprising: an aperture lens plate body, the aperture lens plate body including: an array of N beamlet openings, the array of N beamlet openings having beamlet openings, the array of N beamlet openings configured to generate N primary charged particle beamlets, wherein N is a number >=2; and a plurality of correction openings through the aperture lens plate body configured to locally influence a lens field of the beamlet openings, wherein the correction openings are different than the beamlet openings; and an aperture plate in a field-free region, distant and downstream of the multi-aperture lens plate with an aperture plate body having a plurality of N openings for passing of the N primary charged particle beamlets, the aperture plate body configured to block electrons passing through the correction openings. Particularly, according to some embodiments, which can be combined with other embodiments described herein, the multi-aperture lens plate is arranged for being directly illuminated with the primary charged particle beam, i.e. without having a condenser lens or another lens in between the charged particle emitter and the multi-aperture lens plate.

Embodiment 13. The multi-beam generator of embodiment 12, further comprising: one or more electrodes with a common opening configured for passing of at least one of the primary charged particle beam or the N primary charged particle beamlets, the one or more electrodes being configured to generate an electric field on the multi-aperture lens plate to focus the N primary charged particle beamlets in a plane downstream of the multi-aperture lens plate.

Embodiment 14. The multi-beam generator of any of embodiments 12 to 13, wherein the plane is flat.

Embodiment 15. A charged particle multi-beam apparatus configured to focus N primary charged particle beamlets on a specimen, comprising: a multi-beam generator of any of embodiments 12 to 14.

Embodiment 16. The charged particle multi-beam apparatus of embodiment 15, wherein the array of N beamlet openings and the plurality of correction openings form a first pattern within a first area, wherein further openings are provided in the aperture lens plate body to extend the first pattern beyond the first area to form a second pattern with a second area larger than the first area, wherein the second pattern has an essentially circular shape.

Embodiment 17. A method of generating a plurality of N primary charged particle beamlets to be focused on a specimen, comprising: generating a primary charged particle beam with a charged particle emitter; illuminating a multi-aperture lens plate with the primary charged particle beam; generating beamlets, comprising: generating N primary charged particle beamlets generated with an array of N beamlet openings; and generating first dummy beamlets generated with a plurality of correction openings; focusing the N primary charged particle beamlets with an electric field generated at the multi-aperture lens plate with one or more electrodes, the N primary charged particle beamlets are focused in a plane downstream of the multi-aperture lens plate; and blocking at least the first dummy beamlets, particularly in a field-free region, downstream of the multi-aperture lens plate.

Embodiment 18. The method of embodiment 17, wherein generating beamlets further comprises: generating second dummy beamlets with further openings extending beyond a first area of the array of N beamlet openings and the plurality of correction openings; and blocking the second dummy beamlets.

Embodiments of the present disclosure provide a plurality of advantages, some of which are described in the following: a multi-aperture lens plate can be provided, wherein an octupole aberration from neighboring beamlet openings can be reduced to a smaller aberration with a 16-pole effect. A distortion of the multi-beam generator can be compensated. Field penetration through the beamlet openings can be compensated. Accordingly, an improved array of primary charged particle beamlets with an improved pitch uniformity and/or with reduced aberrations in the primary charged particle beamlets can be provided.

While the foregoing is directed to embodiments, other and further embodiments may be devised without departing from the basic scope thereof, and the scope thereof is determined by the claims that follow.

Listing of claims:

1. A multi-aperture lens plate of a multi-beam generator for a charged particle multi-beam apparatus, comprising:
an aperture lens plate body having one or more layers, the aperture lens plate body comprising:
an array of N beamlet openings through all of the one or more layers, the array of N beamlet openings having beamlet openings, the array of N beamlet openings configured to generate N primary charged particle beamlets, wherein N is a number >=2; and
a plurality of correction openings through all of the one or more layers of the aperture lens plate body and configured to locally influence a lens field of the beamlet openings, wherein the correction openings are different than the beamlet openings.

2. The multi-aperture lens plate of claim 1, wherein the beamlet openings are circular.

3. The multi-aperture lens plate of claim 1, wherein the correction openings are circular.

4. The multi-aperture lens plate of claim 1, wherein the beamlet openings are circular, wherein the correction openings are circular and have a different diameter than the beamlet openings.

5. The multi-aperture lens plate of claim 1, wherein the correction openings have a diameter of 60% of the diameter of the beamlet openings or smaller, particularly from 45% to 55% of the diameter of the beamlet openings.

6. The multi-aperture lens plate of claim 1, wherein the beamlet openings have a diameter of 30 to 70 μm and the correction openings have a diameter of 10 to 30 μm.

7. The multi-aperture lens plate of claim 1, wherein the array of N beamlet openings is rectangular or square.

8. The multi-aperture lens plate of claim 1, wherein a first neighboring beamlet opening of a first beamlet opening of the array of N beamlet openings is in a first direction having a first vector selected from the group consisting of: [1,0], [0,1], [−1,0], and [0,−1] and a first neighboring correction opening of the first beamlet opening is in a second direction selected from the group consisting of: [½, ½], [½, −½], [−½, ½] and [−½,−½].

9. The multi-aperture lens plate of claim 1, wherein the plurality of correction openings is located at equal distance to surrounding beamlet openings of the array of N beamlet openings.

10. The multi-aperture lens plate of claim 1, wherein a position of beamlet openings changes with a distance of the beamlet openings to a central point according to a linear function, a third order function, and/or a fifth order function of the distance.

11. The multi-aperture lens plate of claim 1, wherein the aperture lens plate body includes a foil having a thickness of 20 μm or below, and wherein the array of N beamlet openings and the plurality of correction openings are provided through the foil.

12. A multi-beam generator for a charged particle multi-beam apparatus, comprising:
a charged particle emitter configured to emit a primary charged particle beam;
a multi-aperture lens plate being arranged for being illuminated with the primary charged particle beam, the multi-aperture lens plate comprising:
an aperture lens plate body, the aperture lens plate body comprising:
an array of N beamlet openings, the array of N beamlet openings having beamlet openings, the array of N beamlet openings configured to generate N primary charged particle beamlets, wherein N is a number >=2; and
a plurality of correction openings through the aperture lens plate body configured to locally influence a lens field of the beamlet openings, wherein the correction openings are different than the beamlet openings; and
an aperture plate in a field-free region, distant and downstream of the multi-aperture lens plate with an aperture plate body having a plurality of N openings for passing of the N primary charged particle beamlets, the aperture plate body configured to block electrons passing through the correction openings.

13. The multi-beam generator of claim 12, further comprising:
one or more electrodes with a common opening configured for passing of at least one of the primary charged particle beam or the N primary charged particle beamlets, the one or more electrodes being configured to generate an electric field on the multi-aperture lens plate to focus the N primary charged particle beamlets in a plane downstream of the multi-aperture lens plate.

14. The multi-beam generator of claim 13, wherein the plane is flat.

15. A charged particle multi-beam apparatus configured to focus N primary charged particle beamlets on a specimen, comprising:
a multi-beam generator of claim 12.

16. The charged particle multi-beam apparatus of claim 15, wherein the array of N beamlet openings and the plurality of correction openings form a first pattern within a first area, wherein further openings are provided in the aperture lens plate body to extend the first pattern beyond the first area to form a second pattern with a second area larger than the first area, wherein the second pattern has an essentially circular shape.

17. A method of generating a plurality of N primary charged particle beamlets to be focused on a specimen, comprising:
generating a primary charged particle beam with a charged particle emitter;
illuminating a multi-aperture lens plate with the primary charged particle beam;
generating beamlets, comprising:
generating N primary charged particle beamlets generated with an array of N beamlet openings; and
generating first dummy beamlets generated with a plurality of correction openings;
focusing the N primary charged particle beamlets with an electric field generated at the multi-aperture lens plate with one or more electrodes, the N primary charged particle beamlets are focused in a plane downstream of the multi-aperture lens plate; and
blocking at least the first dummy beamlets, particularly in a field-free region, downstream of the multi-aperture lens plate.

18. The method of claim 17, wherein generating beamlets further comprises:
generating second dummy beamlets with further openings extending beyond a first area of the array of N beamlet openings and the plurality of correction openings; and
blocking the second dummy beamlets.
